(19) United States
(12) Patent Application Publication
(10) Pub. No.: US 2014/0231765 A1
(43) Pub. Date: Aug. 21, 2014

(54) REMOTE DOPING OF ORGANIC THIN FILM TRANSISTORS

(71) Applicants: The Trustees of Princeton University, Princeton, NJ (US); Georgia Tech Research Corporation, Atlanta, GA (US)

(72) Inventors: Wei ZHAO, Gainesville, FL (US); Yabing QI, Plainsboro, NJ (US); Antoine KAHN, Princeton, NJ (US); Seth R. MARDER, Atlanta, GA (US); Stephen BARLOW, Atlanta, GA (US)

(73) Assignees: The Trustees of Princeton University, Princeton, NJ (US); Georgia Tech Research Corporation, Atlanta, GA (US)

(21) Appl. No.: 14/092,523

(22) Filed: Nov. 27, 2013

Related U.S. Application Data
(63) Continuation of application No. 13/094,608, filed on Apr. 26, 2011, now abandoned.
(60) Provisional application No. 61/328,287, filed on Apr. 27, 2010.
(60) Provisional application No. 61/349,446, filed on May 28, 2010.

(51) Int. Cl. H01L 51/00; H01L 51/05

(52) U.S. Cl. CPC H01L 51/0067; H01L 51/0558; H01L 51/0084
USPC 257/40; 438/99

(57) ABSTRACT

Organic electronic devices comprising “remotely” doped materials comprising a combination of at least three layers. Such devices can include “remotely p-doped” structures comprising: a channel layer comprising at least one organic semiconductor channel material; a dopant layer, which comprises at least one p-dopant material and optionally at least one organic hole transport material; and a spacer layer disposed between and in electrical contact with both the channel layer and the dopant layer, comprising an organic semiconducting spacer material; or alternatively can include “remotely n-doped” structures comprising a combination of at least three layers: a channel layer comprising at least one organic semiconductor channel material; a dopant layer which comprises at least one organic electron transport material doped with an n-dopant material; and a spacer layer disposed between and in electrical contact with the channel layer and the dopant layer, comprising an organic semiconducting spacer material. Such devices include “remotely doped” field effect transistors comprising the doped structures described above.

### CROSS-REFERENCE TO RELATED APPLICATIONS

This application claims the priority of U.S. Provisional Application No. 61/328,287 filed 27 Apr. 2010, and also claims the priority of U.S. Provisional Application No. 61/349,446 filed 28 May 2010, the entire content of both US Provisional applications being incorporated herein by reference for all purposes.

### STATEMENT OF GOVERNMENT LICENSE RIGHTS

The Princeton inventors received partial funding support through the National Science Foundation under Grant Number DMR-0705920 and the Princeton MRSEC of the National Science Foundation under Grant number DMR-0819860. The Georgia Tech inventors received partial funding support through the National Science Foundation under Grant Number DMR-0805259 and the Department of Energy, Basic Energy Sciences under Grant number DE-FG02-07ER46467. The Federal Government has certain license rights in this invention.

### TECHNICAL FIELD OF THE INVENTION

The various inventions disclosed, described, and/or claimed herein relate to the field of field effect transistors employing a channel layer comprising at least one organic semiconductor channel material, and “remote” doping of current carriers into that channel layer by dispersing “p” or “n” type dopants disposed in additional dopant layers and/or spacer layers of the devices, and methods for the production of such organic field effect transistors.

### BACKGROUND OF THE INVENTION

Production of components of electronic devices such as transistors from inorganic semiconductors such as silicon, germanium, or gallium arsenide, as well as the use of “dopants” for producing such inorganic semiconductors is very well known in the art. Atoms of “n-dopant” elements that comprise one or more extra valence electrons (as compared to the basic semiconductor material) are typically directly substituted into the inorganic semiconductor lattice as impurities, and thereby provide potentially current-carrying electrons to the delocalized conduction bands that occur in such “n-type” inorganic semiconductors. Similarly, atoms of “p-dopant” elements that comprise or one or more less valence electrons as compared to the basic semiconductor material are typically directly substituted into the inorganic semiconductor lattice as impurities, and thereby provide potentially current-carrying positively charged “holes” into the delocalized conduction bands of “p-type” inorganic semiconductors.

Technology for directly “doping” traditional inorganic semiconductors is very well known and developed, and produces electronic semiconductors with very good electrical performance, but the production costs can be very high.

The technique of “modulation doping” inorganic semiconductors is also known in the art, wherein multiple alternating layers of narrow band gap and wider band gap semiconductor materials are employed, with dopants applied only in the layers of the wider band gap material. See for example U.S. Pat. No. 4,163,237, and/or Soloman et al, IEEE Transactions on Electrical Devices, Vol Ed-31, No. 8, 1015-1027, 1984. In such multiple layer inorganic semiconductor devices, charge carriers from the dopant in the wide band gap semiconductor layer migrate to the “remote” layer of undoped narrow band gap material, and dramatically increase its conductivity. The ionized dopant atoms remain in the wide-band gap layer, and therefore cannot cause significant coulombic trapping or scattering in the conduction bands of the remote layer having the narrow band gap material. U.S. Pat. No. 4,163,237 teaches however that the lattices of the narrow and wide band gap materials must “match” at their interface to avoid the creation of defects, a requirement that very much narrows the range of semiconductor materials that can be combined and employed in such inorganic devices.

There has been much recent work directed toward developing large area and/or “printable” electronic components and devices based on “organic” semiconductors that comprise organic small molecules or polymers that can potentially be made at much lower cost by solution processing, perhaps on flexible substrates such as plastic or paper. However, there are many important differences between the inorganic and organic semiconductors. For example, there are no completely delocalized “bands” or “conduction states” for electrons or holes extending throughout organic semiconductors.

The conduction of current, in the form of either holes or electrons, typically occurs by quantum mechanical “hopping” between the separate organic molecules, rather than conduction through the whole solid via delocalized “bands”. As a result of such differences, the charge carrier mobilities and/or some other electrical properties of currently known organic semiconductor materials are, at least at the present time, significantly different and often less desirable than those of the inorganic semiconductors. However, the organic materials offer the potential for an almost infinite variety of structures so as to allow a wide variety of properties, including potential flexibility in the solid state so as to allow for flexible devices, and lower cost solution processing to make large area devices at low cost. Therefore, there remains a need in the art for technologies that can improve the electrical performance of organic semiconductors.

Controlled direct chemical doping into organic semiconductor materials is known in the art as an effective technique to improve the electrical performance of some types of organic semiconducting materials and/or devices, such as organic light-emitting diodes (OLEDs, see for example Walzer et al, Chem. Rev. 2007, 107, 1233-127, and Zhao et al, Adv. Funct. Mater. 2001, 11, No. 4), and photovoltaic cells (see for example Uhrich et al, J. Applied Physics, 104, 043107, 2009, and Chan et al, Applied Physics Letters, 94, 203306, 2009).

2,3,5,6-Tetrafluoro-7,7,8,8-tetracyanoquinodimethane (F₄-TCNQ) is probably the best known organic compound for directly p-doping organic hole carrying semiconductor materials, but often suffers from diffusional instability within the organic semiconductor materials. A high electron affinity molybdenum dithiolene complex (“Mo(tfd)₃”) has recently been disclosed as a diffusion-resistant p-dopant for organic hole carrying materials, see Qi et al, J. Am. Chem. Soc. 2009, 131, 12530-12531, and Chem. Mater. 2010, 22, 524-531. Similarly, cobaltocene (Co(C₅H₅)₂) and decamethylcobaltocene (Co(C₅Me₅)₂) were recently disclosed as n-dopants for organic electron carrying materials, see Chan et al, Organic Electronics 9 (2008) 575-581, and U.S. Patent Publication 2007/029594.

It is believed in the art that two major effects of directly doping organic semiconductor materials, in either p-type or n-type organic semiconductors, is (i) increasing the density of “free” carriers available for conduction, and (ii) preferential filling of deep traps in the gaps of the organic semiconductors, thereby reducing the activation energy required for the “hopping” transport process of the injected current carriers from molecule to molecule, which can produce a substantial increase charge-carrier mobility. Additionally, directly doping organic materials used in OLEDs and photovoltaic cells can reduce contact resistances by providing improved electron or hole tunneling through narrow interface depletion regions, and manipulation of the molecular energy level alignments at organic-organic heterojunctions can sometimes provide orders-of-magnitude increases in organic film conductivity.

However, directly introducing a relatively high concentration of ionizable dopants into the corresponding electron or hole carriers in the organic matrix can lead to disruption of the host matrix, or to coulombic trapping or scattering of electron or hole carriers by the remaining ionized local dopant, so that increasing concentrations of dopants past an optimum and typically small level can actually decrease conductivity. These effects are known but not completely understood, and likely depend on both the chemical structure of specific organic compounds and the corresponding physical properties of the solid organic thin film (crystalline vs. polycrystalline, or amorphous, etc).

Moreover, the attempted application of direct doping in organic semiconductor thin-film transistors (OFETs) has not been very successful, because of difficulties in controlling the charge density in the doped channel of organic thin film field effect transistors, and/or corresponding difficulties in switching the current on and off in response to a gate voltage. See for example Matsushima et al, Thin Solid Films, 517 (2008) 74-877, Kim et al, Chem. Mater. 2009, 21, 4583-4588, Ma et al, Appl. Phys. Lett 92, 063310 (2008), and Lim et al, J. Mater. Chem., 2007, 17, 1416-1420.

An “indirect” approach to doping field effect transistors comprising organic semiconductors has also been reported, see Abe et al, Appl. Phys. Lett. 87, 153506 (2005). Abe reported a bottom gate OFET comprising a pentacene semiconductor layer, whose upper surface was indirectly doped by depositing F₄-TCNQ dopant to fractional percentages of the upper pentacene surface (between the top contact electrodes). Increasing fractional coverage of the pentacene surface with F₄-TCNQ substantially increased the current and/or hole mobility of the pentacene semiconductor (up to about 10±0.1 cm²/Vs), but the ability to switch the transistor off in response to gate voltage declined with increasing dopant coverage, and at fractional coverages of the pentacene surface by the F₄-TCNQ dopant of more than about 0.7, the transistor channel current could not be effectively turned off in response to applied gate voltage.

Accordingly, there remains an unmet need in the art for improved field effect transistors comprising organic semiconductors. It is to that end that the various embodiments of the inventions described below are directed.

### SUMMARY OF THE INVENTION

The various inventions and/or their many embodiments disclosed herein relate to components of electronic devices that comprise “remotely doped” semiconductor devices comprising a combination of at least three layers. Such devices can include “remotely p-doped” structures comprising:
a. a channel layer comprising at least one organic semiconductor channel material:
b. a dopant layer, which comprises at least one p-dopant material and optionally at least one organic hole transport material;
c. a spacer layer disposed between and in electrical contact with both the channel layer and the dopant layer, comprising at least one organic semiconducting spacer material;
   or alternatively remotely n-doped structures comprising a combination of at least three layers:
a. a channel layer comprising at least one organic semiconductor channel material;
b. a dopant layer which comprises at least one organic electron transport material doped with an n-dopant material
c. a spacer layer disposed between and in electrical contact with the channel layer and the dopant layer, comprising at least one organic semiconducting spacer material.

Such remotely doped devices which have an undoped “spacer” layer have been discovered by the Applicants to be particularly and unexpectedly effective for improving the electrical performance of organic field effect transistors (“OFETs”), while maintaining the capability for turning the transistors on or off in response to the gate voltage/field. Accordingly, in some broad aspects the inventions disclosed and described herein relate to “remotely” p-doped organic field effect transistors comprising
a. a channel layer comprising at least one organic semiconductor channel material:
b. a dopant layer, which comprises at least one p-dopant material and optionally at least one organic hole transport material;
c. a spacer layer disposed between and in electrical contact with both the channel layer and the dopant layer, comprising at least one organic semiconducting spacer material;
d. source and drain electrodes in electrical contact with the channel layer, and
e. a gate electrode in contact with a gate insulating layer.

In other related broad aspects the inventions disclosed and described herein relate to a “remotely” n-doped field effect transistor comprising
a. a channel layer comprising at least one organic semiconductor channel material;
b. a dopant layer which comprises at least one n-dopant material and optionally at least one organic electron transport material;
c. a spacer layer disposed between and in electrical contact with the channel layer and the dopant layer, comprising at least one organic semiconducting spacer material;
d. source and drain electrodes in electrical contact with the channel layer; and
e. a gate electrode in contact with a gate insulating layer.

The various inventions disclosed and described herein also relate to methods for making such “remotely” doped organic semiconductor structures and devices. Such structures and devices, and methods for making them, are useful for making a wide variety of electronic devices.

Further detailed description of preferred embodiments of the various inventions broadly outlined above will be provided below in the Detailed Description section provided below. All references, patents, applications, tests, standards, documents, publications, brochures, texts, articles, etc. mentioned herein, either above or below, are incorporated herein by reference.

### BRIEF DESCRIPTION OF THE FIGURES

FIG. 1a discloses UPS spectra of pentacene incrementally deposited on 1% p-doped α-NPD. Vertical bars indicate the work function (left panel) and the HOMO edge (right panel). The Fermi level (E_{F}) is the reference 0 eV energy.

FIG. 1b discloses an expanded view of pentacene-based ionizations close to E_{F}, showing a 0.15 eV rigid shift between the 10 Å and 80 Å pentacene films.

FIG. 1c discloses an energy level diagram of the 1% p-doped α-NPD/pentacene heterojunction based on FIGS. 1(a) and 1(b). See Example 1.

FIG. 2 discloses a graph of conductivity (σ) vs. inverse temperature for the devices described in Example 2, comprising (a) a pentacene layer (400 Å); and a spacer layer, and a dopant layer comprising p-doped (1% Mo(tfd)3)α-NPD (400 Å), wherein the spacer layer was (b) FIrpic (100 Å); or (c) undoped α-NPD (100 Å); (d) or (d) no interlayer. The dashed line shows σ of a separate device comprising a 5000 Å 1.7% p-doped α-NPD film. The Inset shows the top view and cross section of the device layout and electrode arrangement for the non-gated conductivity measurements.

FIG. 3 discloses a graph of the transfer characteristics of the four bottom gate, top contact field effect transistors described in Example 3.

FIG. 4 shows a schematic diagram of the remotely n-doped OFET whose preparation is described in Example 5.

### DETAILED DESCRIPTION OF THE INVENTION

Many aspects and other features or embodiments of the broad inventions initially disclosed and described above will now be set forth more fully in the detailed description that follows, as will become apparent to those having ordinary skill in the art upon examination of the following or may be learned from the background information and prior art, and practice of the present invention. The advantages of some aspects or embodiments of the inventions described herein can be realized and obtained as particularly pointed out in the appended claims. As will be realized, the present invention is capable of other and different embodiments, and its several details are capable of modifications in various obvious respects, all without departing from the present invention. The description below is to be regarded as illustrative in nature, and not as restrictive.

### Remotely Doped Organic Semiconductor Devices

In their many aspects and/or embodiments, the inventions disclosed and described herein relate to “remotely doped” organic semiconductor devices that comprise at least three layers, a channel layer, a dopant layer, and a spacer layer disposed between and in electrical contact with both the channel layer and the dopant layer. Applicants have discovered that inclusion of a spacer layer in such remotely doped organic semiconductor devices provides unexpected opportunities for both improving and simultaneously controlling the electrical performance of such remotely doped organic semiconductor devices.

The remotely doped organic semiconductor devices can be constructed with either “n-type dopants and corresponding “n-type” organic semiconductors, or with “p-type” dopants and “p-type” organic semiconductors.

The organic semiconductor materials described herein are typically solids that comprise organic (carbon containing) small molecules, oligomers, polymers, or copolymers that contain carbon atoms bound together by double or triple bonds, so that the compounds comprise conjugated and potentially delocalized π-bonds that can potentially carry holes or electrons. Many such organic semiconductor channel materials also comprise optionally substituted aryl or heteroaryl rings, preferably conjugated to each other, to form at least partially delocalized systems of π bonds. Organic semiconductor channel materials suitable for conducting holes (“p-type” organic semiconductor materials) typically have highest occupied molecular orbitals (“HOMOs”) that are part of a delocalized systems of π bonds of relatively high energy, so that is relatively easy for an electron to be removed from the HOMO, so as to leave behind in the HOMO a positively charged “hole” that can carry electrical current. Organic semiconductor channel materials suitable for conducting electrons (“n-type” organic semiconductor materials) typically have lowest unoccupied molecular orbitals (“LUMOs”) that are unoccupied by available as a result of a delocalized systems of π bonds, and are of relatively low energy, so that is relatively easy for an electron to be added to the delocalized LUMO, so as to generate a negatively charged electron that can carry electrical current.

“Remotely p-doped” devices comprise at least:
a. a channel layer comprising at least one organic semiconductor channel material:
b. a dopant layer, which comprises at least one p-dopant material and optionally at least one organic hole transport material;
c. a spacer layer disposed between and in electrical contact with both the channel layer and the dopant layer, comprising at least one organic semiconducting spacer material;

“Remotely n-doped” devices comprise at least:
a. a channel layer comprising at least one organic semiconductor channel material;
b. a dopant layer which comprises at least one organic electron transport material doped with an n-dopant material
c. a spacer layer disposed between and in electrical contact with the channel layer and the dopant layer, comprising at least one organic semiconducting spacer material.

Such remotely doped devices have been discovered to be particularly and unexpectedly effective for improving and/or controlling the electrical performance of organic field effect transistors (“OFETs”). Accordingly, in some broad aspects, the inventions disclosed and described herein relate to “remotely” p-doped organic field effect transistors and “remotely” n-doped organic field effect transistors derived from the remotely p-doped devices described above that comprise at least two additional components:
a. source and drain electrodes in electrical contact with the channel layer; and
b. a gate electrode in contact with a gate insulating layer.

The transistors comprise source and drain electrodes, in physical or electrical contact with the channel layer, and a gate electrode and its gate insulating (i.e. dielectric) layer. As is well known in the art, the gate electrode and its gate insulating are typically disposed or positioned either adjacent to or in physical contact with the channel layer, so that an external electric field can be applied to the channel (and/or dopant and spacer layers), so as to modulate (and/or turn on or off) current flowing in the channel layer. Many alternative geometries, schemes and methods for electrically connecting or physically orienting the source and drain electrodes, and/or the gate electrode/gate insulating layer with respect to the channel layer are known in the art and can be employed (top gate, bottom gate, etc). In many embodiments of the field effect transistors of this invention, the gate insulating layer is in physical contact with a surface of the channel layer (i.e. a bottom gate configuration).

The first of the three core layers of the remotely doped devices is a “channel layer”, comprising at least one organic semiconductor channel material, whose dimensions, chemical, physical, and electrical properties are chosen to be suitable for the purpose of conducting electrical current through the device with relatively high electrical carrier mobility, and relatively low resistance, so that electrical holes or electrons can be conducted through the channel layer with relatively high efficiency. Suitable organic semiconductor channel materials would typically have intrinsic (undoped) electrical conductivity between about 100 and about 1×10⁻⁴ Siemens per centimeter. The thickness of the channel layers can be between about 2 and about 500 Angstroms, or between about 50 and about 200 Angstroms. Further details and properties relating to the channel layer will be further elaborated below.

The third of the three core layers is a “remote” dopant layer, which comprises at least one dopant material, and optionally at least one organic hole transport material, or optionally at least one organic electron transport material. One function of the dopant layer is to (potentially reversibly) supply additional current carriers (holes or electrons) to the channel and/or spacer layers, so as to substantially increase or decrease the electrical conductivity (or current flow) in the channel layer.

In some embodiments of the devices, the dopant material (either a p-dopant material or an n-dopant material) can be applied directly to the surface of the spacer layer, in the absence of other materials. In many embodiments of the devices, the dopant material can be dispersed into or co-deposited with another material, including the optional at least one organic hole transport material, or optional at least one organic electron transport material, in any proportion desired, to form the dopant layer. Preferably the dopant material is relatively immobile (i.e. doesn't substantially diffuse) in the at least one organic hole transport material, or at least one organic electron transport material, at the operating temperatures of the devices. The dopant layer may be applied to the spacer layer by any of the vacuum deposition, co-deposition, or solution application processes known in the art, to form a dopant layer of any desired thickness. In many embodiments, the dopant layer has a thickness between about 2 and about 500, or between about 50 and about 200 Angstroms.

The optional organic hole transport material or organic electron transport material in the dopant layers are typically organic semiconductors capable of reversibly accepting holes or electrons from the dopant material, and dispersing and/or transmitting them to the spacer and/or channel layers. Their undoped electrical conductivity and/or carrier mobility is typically chosen to be at least 100 fold less than that of the organic semiconductor channel material, so that the contributions of the dopant layer to the overall electrical current passing though the device are intentionally insignificant compared to electrical current passing though the channel layer. Further details and properties relating to the dopant layer, the dopant materials, and the organic hole transport material and the organic electron transport material will be further described below.

The second of the three layers, a “spacer layer”, which is disposed between and in electrical and/or physical contact with both the channel layer and the dopant layer, comprises an organic semiconducting spacer material, and typically is not doped. The organic semiconducting spacer material may be the same material as the organic hole transport material or organic electron transport material, or it may be a different organic semiconductor material, as will be further disclosed below. The organic semiconducting spacer material is typically an organic semiconductor capable of reversibly mediating or even impeding the transfer of holes or electrons between the channel layer and the dopant layer (typically in response to electrical fields supplied by the gate electrodes of OFET devices). As with the organic hole transport material and/or the organic electron transport material, the electrical conductivity and/or carrier mobility of the organic semiconducting spacer material is also is typically chosen to be at least 100 fold less than that of the organic semiconductor channel material, with the result that the contributions of the spacer layer to the overall electrical current passing though the device are insignificant compared to electrical current passing though the channel layer.

The spacer layer is an important component of the inventions described herein, and can have any one or all of several important functions, not all of which are currently well understood. Applicants have discovered (as illustrated in Example 3) that the spacer layer employed in organic field effect transistors can (depending on its composition, energetic and conduction properties, thickness, etc) dramatically and unexpectedly effect and/or improve the ability to “turn off” current flow in the channel layer in response to the application of appropriate voltages to the gate electrode, by drawing holes or electrons toward, or driving them away from the channel layer.

Without wishing to be bound by theory, Applicants believe that the spacer layer can serve a remote “storage” layer for holes or electrons being purposely driven away from the channel layer by application of the gate field. Alternatively, if the thickness and properties of the spacer layer are appropriately chosen, the spacer layer may serve as a physical and energetic “barrier” to the tunneling of holes or electrons between the channel and dopant layers, which can be overcome by the application of an appropriate gate field, so as to improve the ability to modulate the current flowing through the channel layer.

Without wishing to be bound by theory, it is believed that another important function of the spacer layer is to provide physical and coulombic separation between the holes or electrons supplied to the channel layer and the correspondingly ionized dopant material in the dopant layer, so that the electrical current of holes or electrons in the channel layer are not strongly effected by or scattered by coulombic attraction to the ionized and immobile dopant materials in the dopant layer, which therefore do not scatter or impede current flow in the channel layer.

Clearly, the thickness, composition, and physical and energetic properties of the spacer layer and/or the organic semiconducting spacer material, in relationship to the corresponding properties of the channel layer and dopant layer can be important and/or inter-related. In many embodiments, the spacer layer has a thickness between about 2 and about 500 Angstroms, or between about 50 and about 200 Angstroms.

“Remotely” p-Doped Organic Field Effect Transistors

In many embodiments, the inventions relate to “remotely” p-doped organic field effect transistors (“p-OFETs”) comprising
a. a channel layer comprising at least one organic semiconductor channel material:
b. a dopant layer, which comprises at least one p-dopant material and optionally at least one organic hole transport material;
c. a spacer layer disposed between and in electrical contact with both the channel layer and the dopant layer, comprising an organic semiconducting spacer material;
d. source and drain electrodes in electrical contact with the channel layer; and
e. a gate electrode in contact with a gate insulating layer.

In many embodiments of the p-OFETs, the organic semiconductor channel material is an organic hole-transport material. Organic hole transport materials typically comprise one or more organic compounds comprising two or more conjugated aryl or heteroaryl rings with relatively high energy HOMO orbitals, and therefore have an ionization energy, as measured by photoemission spectroscopy, of less than about 6.0 eV, or preferably between about 5.0 and about 6.0 eV. Although many such organic hole-transport materials are known, preferably an organic hole-transport material suitable as an organic semiconductor channel material has a relatively high intrinsic conductivity and/or intrinsic hole mobility, for example an intrinsic hole mobility larger than 1×10⁻³ cm²/(V sec), or preferably larger than 1×10⁻² cm²/(V sec). When remotely p-doped as described herein, the conductivity and/or hole mobility measurable in the channel layer of the devices can be very substantially increased, preferably at least by a factor of two, or preferably at least a factor of 10.

In many embodiments, the organic semiconductor channel material comprises a crystalline or semi-crystalline hole-transport material. Examples of such materials include pentacene or a substituted pentacene derivative such as TIPS pentacene (6,13-bis(triisopropyl-silylethynyl)pentacene), rubrene or a rubrene derivative, a metallo phthalocyanine, such as copper phthalocyanine or zinc phthalocyanine, or a regioregular alkyl polythiophene, whose structures are shown below.

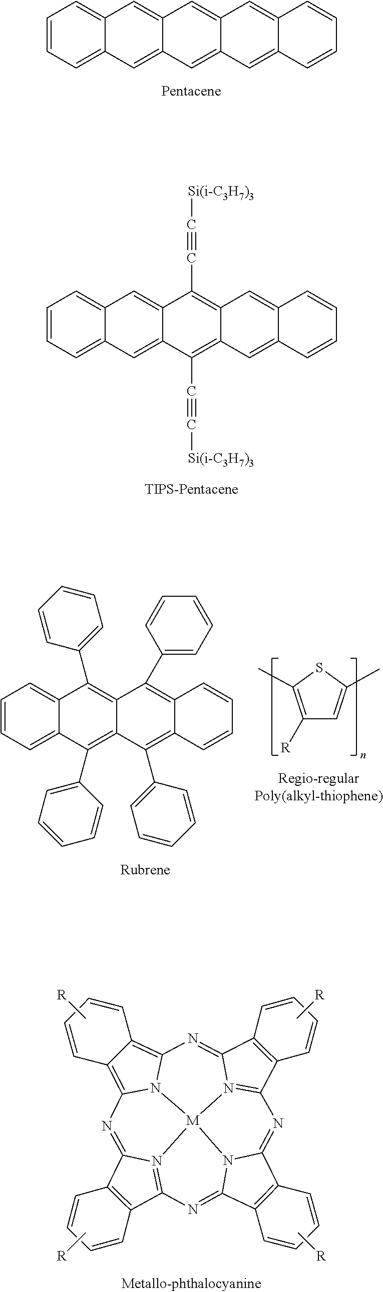

In some embodiments, the organic semiconductor channel material comprises an amorphous hole-transport material, such as for example the well known class of poly(triarylamines), whose structure is shown below, where R can be a variety of substituent groups, such as alkyls, alkoxys, and the like.

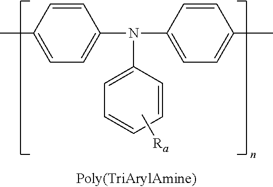

Additional examples of amorphous organic semiconductor channel materials that are hole transport materials include the thiazolothiazole copolymers disclosed in WO 2008/100084 that have the structure shown below:

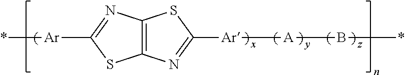

wherein Ar and Ar′ are bivalent cyclic or non-cyclic hydrocarbon or heterocyclic groups having a conjugated structure, and A and B are arylene or heteroarylene groups such as

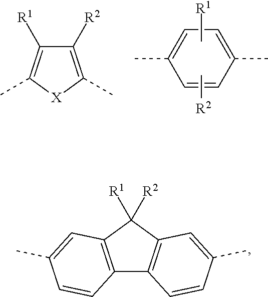

or the benzobisthiazole/alkylthiophene copolymers such as PBTOT disclosed by Ahmed et al, Macromolecules 2009, 42, 8615-8618,

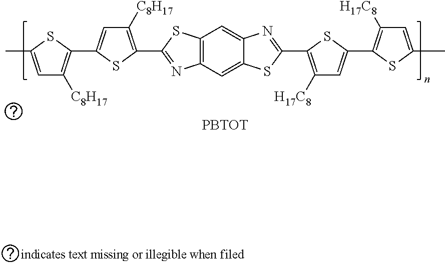

the poly(9,9-dialkyfluorene-co-N,N′-bis(4-alklphenyl)-N,N′-diphenyl-1,4-phenylenediamine) (“PFB”) copolymers.

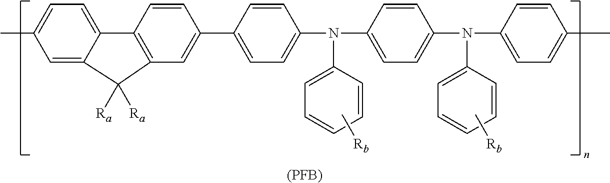

In some embodiments, the organic semiconductor channel material comprises a mixture or composite of both a crystalline or semi-crystalline hole-transport material or an amorphous hole-transport material. Such processable composites (such as a combination of poly(triarylamines) such as a composite of PTAA and TIPS pentacene, wherein the TIPS pentacene can form crystals with the amorphous PTAA) can be solution processable.

As already noted, the p-type devices of the invention comprise a dopant layer, which comprises at least one p-dopant material and optionally at least one organic hole transport material. In some embodiments, the p-dopant material is applied directly to the surface of the spacer layer as a pure material. In many embodiments, the dopant layer comprises a composite or mixture of the p-dopant material and at least one organic hole transport material, which can be present in any relative proportion. In many embodiments, dopant layer has a thickness between about 2 and about 500 Angstroms, or between about 50 and about 200 Angstroms.

At least one of the functions of the dopant layer and/or p-dopant material is to provide holes to the channel layer, and/or the spacer layer, by being energetically capable of removing electrons from the hole transport material, the spacer layer, and/or the channel layer. Accordingly the p-dopant material should be a strong oxidant. One such known p-dopant material can be Tetrafluoro TCNQ, whose structure is shown below:

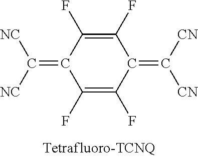 [SMILES: N#CC(C#N)=c1c(F)c(F)c(=C(C#N)C#N)c(F)c1F]

Another known class of p-dopant materials are the transition metal complexes disclosed in WO 2008/061517, which have the six structures shown below:

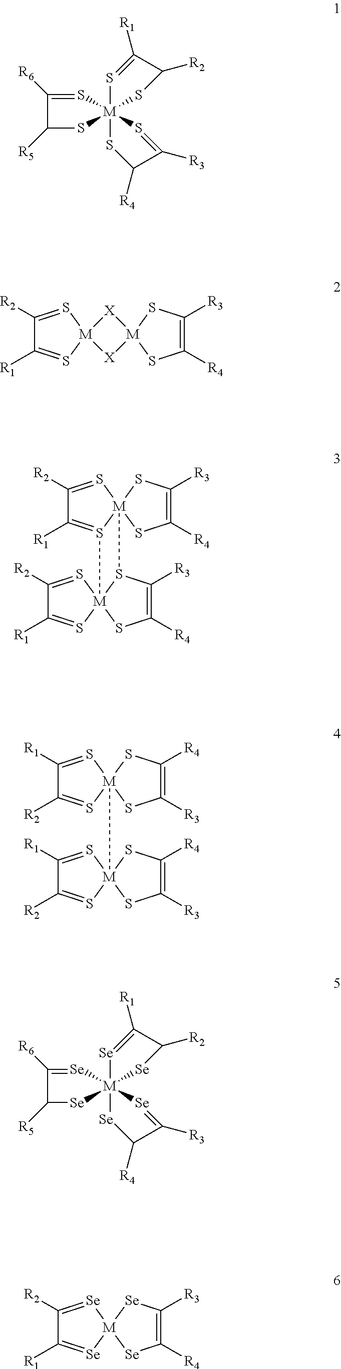

wherein M is transition metal, preferably Cr, Mo, or W, and R₁-R₆ are independently selected from H, substituted or unsubstituted C₁-C₁₀ alkyl, C₁-C₁₀-Thienyl, perfluorinated alkyl, Phenyl, Tolyl, N,N-Dimethylaminophenyl, Anisyl, Benzoyl, CN or COOR₇ where R₇ is C₁-C₅-alkyl; X is S, Se, NR₁₀, wherein R₁₀ is alkyl, perfluoroalkyl, cycloalkyl, aryl, hetero aryl, acetyl or CN.

A known and favored class of p-dopant materials are the transition metal complex having the formula:

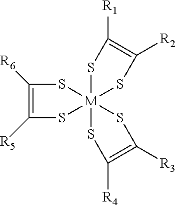

wherein M is Cr, Mo, or W, and R₁-R₆ are independently selected from a C₁-C₃₀ perfluoroalkyl, cyano, or optionally substituted aryl or heteroaryl. A particularly favored complex from this class is Mo(tfd)₃, wherein M is molybdenum and R₁-R₆ are CF₃, which are good oxidants for hole transport materials and are believed to be stable to diffusion within a matrix of hole transport materials at temperatures over 100° C., see Qi et al, Chem. Mater. 2010, 22, 524-531.

In many embodiments, the dopant layer comprises at least one semiconducting organic hole transport material. Suitable organic hole transport materials typically are a solid (and usually amorphous) organic compound comprising at least two conjugated aryl or heteroaryl rings and having a highest occupied molecular orbital that can be reversibly oxidized to remove an electron and create at least one positively charged hole. Preferably the hole conductivity of the organic hole transport material is at least about 1×10⁻⁶ Siemens per centimeter. Preferably, the organic hole transport material has an ionization energy of greater than about 5.4 eV, as measured by photoemission spectroscopy, and a hole mobility that is smaller than the intrinsic hole mobility of the organic semiconductor channel material by a factor of about 100 to about 100,000.

In order for the transfer of electrons to be energetically feasible (at least in the absence of an applied gate field), the dopant layer should have an ionization energy (IE) at least as large, and preferably larger, than the IE of the organic semiconductor channel material. In embodiments wherein the channel layer has an IE of about 5.5 to 6 eV, the dopant layer should have an IE between about 5.5 to 6 eV.

In many embodiments, organic hole transport material is an organic compound comprising two to 10 conjugated triaryl amine subunits having the structure:

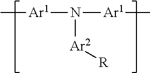

wherein Ar¹ and Ar² can be the same or different and comprise at least one phenyl or napthyl ring, and R is a normal or branched C₁-C₁₈ alkyl group.

In many embodiments, organic hole transport material has one of the structures:

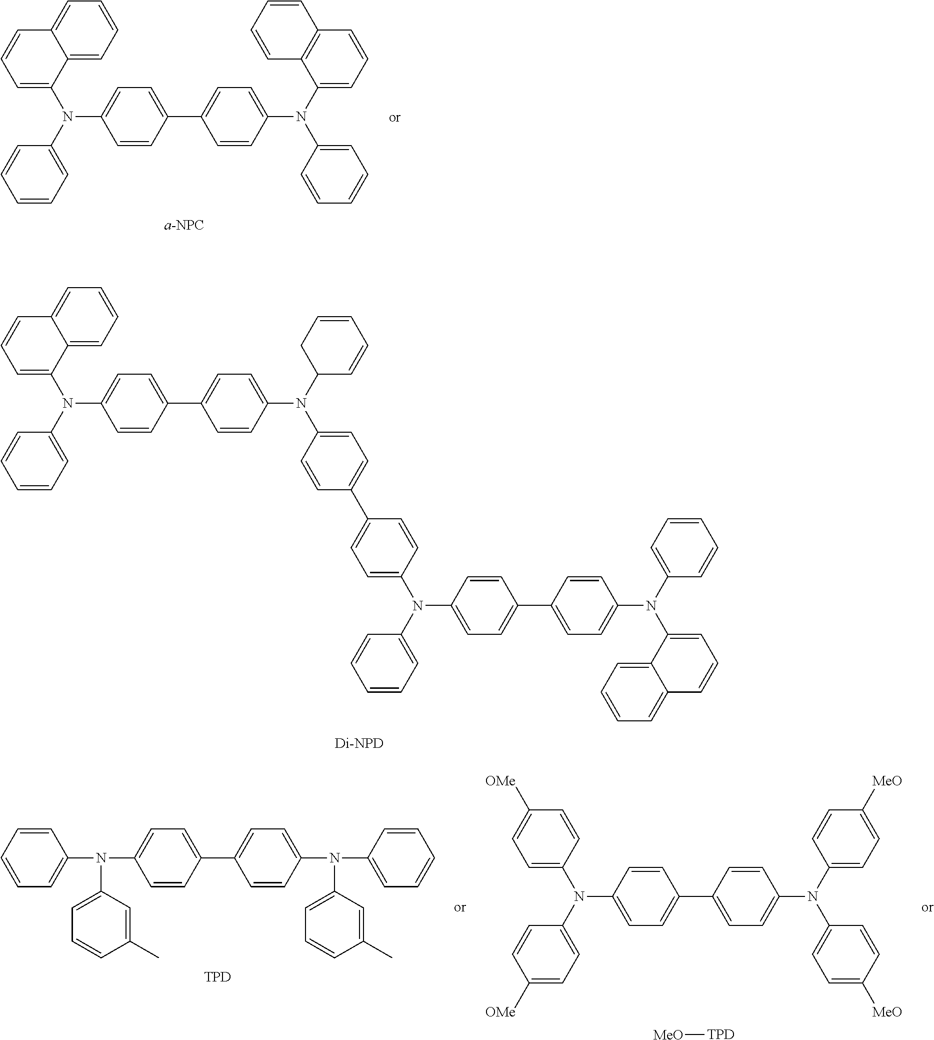

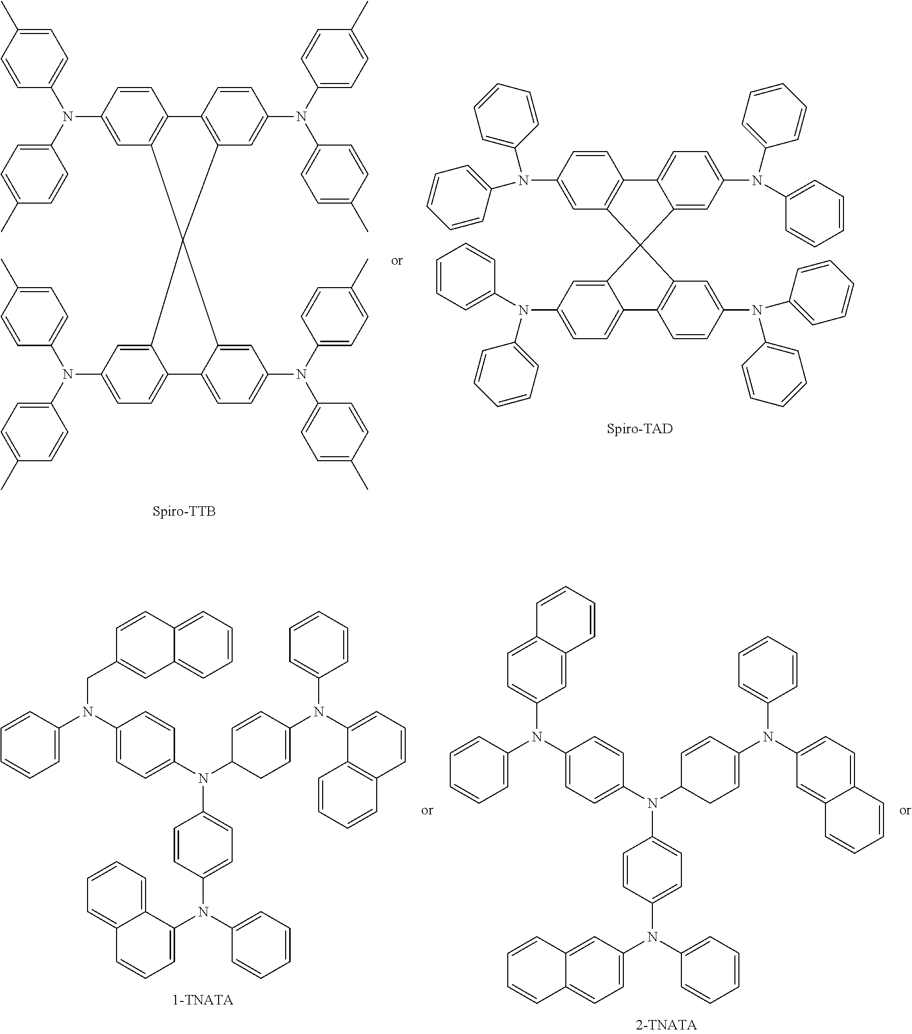

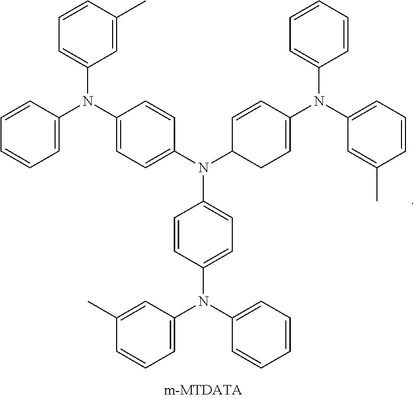 [SMILES: Cc1cccc(N(C2=CCC(N(c3ccc(N(c4ccccc4)c4cccc(C)c4)cc3)c3ccc(N(c4ccccc4)c4cccc(C)c4)cc3)C=C2)c2ccccc2)c1]

As already noted above, the p-type field effect transistors comprise a spacer layer disposed between and in electrical contact with both the channel layer and the dopant layer, comprising an organic semiconducting spacer material. Both the dimensions and the composition of the spacer layer are important to its various functions, including mediating or even purposely impeding the transmission of holes between the channel layer and dopant layer.

The optimal thickness of the spacer layer varies as a function of the materials therein, but typically the spacer layer has a thickness between about 2 and about 500 Angstroms, or between about 50 and about 200 Angstroms.

The organic semiconducting spacer material should have a hole mobility that is significantly smaller than the intrinsic hole mobility of the organic semiconductor channel material, by a factor of about 100 to about 100,000, so that only insignificant amounts of electrical current flow through the spacer layer, and that electrical current flowing though the transistor is dominated by current flow through the channel layer.

The organic semiconducting spacer material typically comprises an organic semiconductor compound comprising two or more conjugated aryl or heteroaryl rings with a relatively high energy HOMO, so that the ionization energy of the spacer layer is at least somewhat larger than that of the channel layer, and equal to or somewhat larger than that of the organic hole transport material. Accordingly, in many embodiments, the ionization energy of the organic semiconducting spacer material, as measured by photoemission spectroscopy, of greater than about 5.4 eV.

The organic semiconducting spacer material can be the same as the organic hole transport material, and hence can be any one or more of the organic hole transport materials already described, such as α-NPD, or a polymeric or copolymeric hole carrier material. Further examples of such polymers or copolymers include TFB or Polydialkylfluorenes, as shown below:

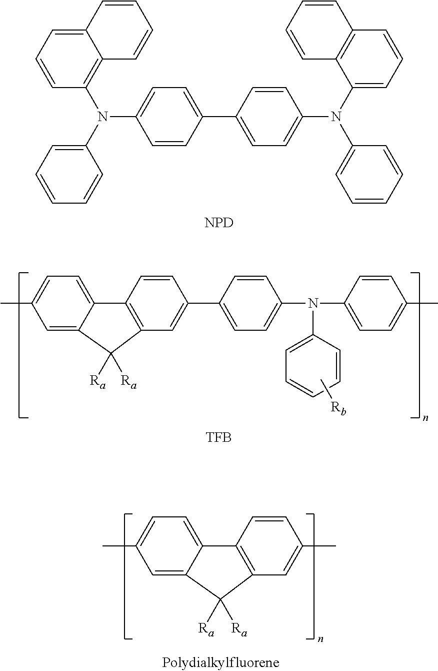

In the embodiments of the p-type field effect transistors wherein the channel layer has an ionization energy between about 5 and about 5.5 eV, and it is desirable to employ the spacer layer as a “barrier layer” to help improve the ability to modulate current flowing in the channel layer in response to the gate field, the spacer layer should preferably have an ionization energy between about 5.5 and about 6.0 eV, or even higher, such as for example an ionization energy, as measured by photoemission spectroscopy, of between about 6.0 and about 7.0 eV. Examples of materials having such ionization energies include fullerenes such as C₆₀ or C₇₀, or their well known soluble derivatives, phenanthrolines such as BCP, N-substituted carbazoles such as CBP, or perylene derivatives such as 3,4,9,10-perylenetetracarboxylic-bis-benzimidazole (PTCBI), Alq3, or FIrPic, whose structures are shown below:

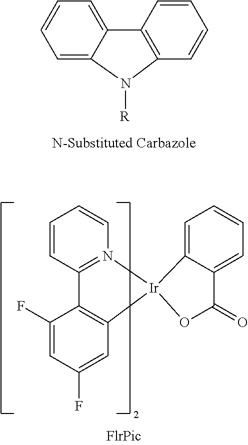

“Remotely” n-Doped Organic Field Effect Transistors

In additional aspects the inventions disclosed and described herein relate “remotely” n-doped field effect transistors comprising
a. a channel layer comprising at least one organic semiconductor channel material;
b. a dopant layer which comprises at least one n-dopant material and optionally at least one organic electron transport material;
c. a spacer layer disposed between and in electrical contact with the channel layer and the dopant layer, comprising an organic semiconducting spacer material;
d. source and drain electrodes in electrical contact with the channel layer, and
e. a gate electrode in contact with a gate insulating layer.

These remotely n-doped field effect transistors are similar in numerous aspects to the p-doped field effect transistors described above, for example the dopant and spacer layers of both types of transistors can each have a thickness between about 2 and about 500 Angstroms, or between about 50 and about 200 Angstroms.

There are however differences, because n-doped field effect transistors have the function of carrying electric current in the form of electrons, rather than holes. For example, in n-doped field effect transistors, the organic semiconductor channel material, the organic electron transport material, and the organic semiconducting spacer material are each electron-transport materials.

Electron transport materials typically comprise one or more organic compounds comprising two or more conjugated aryl or heteroaryl rings with relatively low energy LUMO orbitals having an electron affinity of about 3.5 to about 4.5 eV, as defined by inverse photoemission spectroscopy measurements, to which the n-dopant material readily can donate an electron. It should be understood however that at least some organic semiconductor materials known in the prior art that were demonstrated to be effective hole transport materials (because, at least in part, of the presence of an energetically accessible HOMO) can also have an energetically accessible LUMO orbital that can be n-doped, with the result that what may have been described in the prior art as a “p-type” or “hole transmitting” material can, at least in some cases be n-doped and/or serve, in the context of the present inventions, as an electron transport material.

The spacer layers and dopant layers should have electron affinities as small, or smaller than the electron affinity of the channel layer. If the electron affinity of the spacer layer is significantly smaller than that of the channel layer, it can function as a barrier to the transport of electrons from the dopant layer to the channel layer that can however be overcome by applying positive potentials on the gate of the transistors, so as to aid in switching the n-doped transistors on and off.

Preferably an electron transport material suitable as an organic semiconductor channel material has a relatively high intrinsic conductivity and/or intrinsic electron mobility, for example an intrinsic electron mobility between about 5 and about 1×10⁻⁴ cm²/(V sec), or preferably an intrinsic hole mobility larger than 1×10⁻³ cm²/(V sec), or preferably larger than 1×10⁻² cm²/(V sec). When remotely n-doped as described herein, the conductivity and/or electron mobility measurable in the channel layer of the devices can be very substantially increased, preferably at least by a factor of two, or preferably at least a factor of 10.

In some embodiments, the organic semiconductor channel material is selected from:
a. perfluorinated copper phthalocyanine,

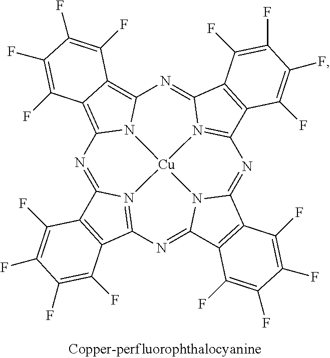

b. dicyanonaphthalene diimides or dicyanoperylene diimides

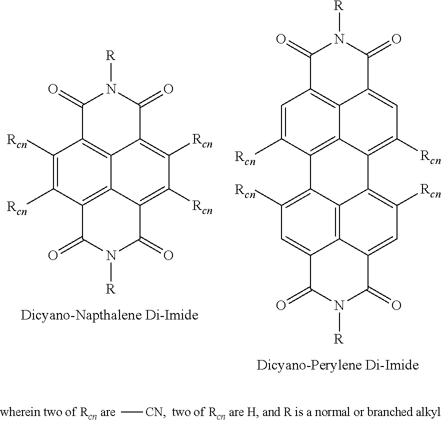

c. 1,4,5,8-Naphthalenetetracarboxylicdianhydride

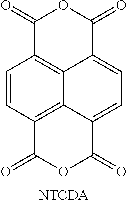

d. TCNQ

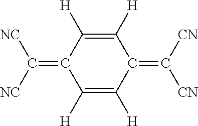 [SMILES: N#CC(C#N)=c1ccc(=C(C#N)C#N)cc1]

e. C₆₀ or a derivative thereof, or
f. C₇ or a derivative thereof.

In some embodiments of the n-type field effect transistors of the inventions, the organic semiconductor channel material is a polymer or copolymer comprising naphthalene diimide or perylene diimide subunits, which have LUMOs with very high electron affinities. Examples of such copolymers are the perylene copolymer disclosed by Zhan et al in J. Am. Chem. Soc. 2007, 129, 7246-7247, whose structure is shown below, or the perylenediimide and/or naphthalenediimide copolymers disclosed in WO 2009/098250, WO 2009/098253, or WO 2009/098254, whose structures are also illustrated below.

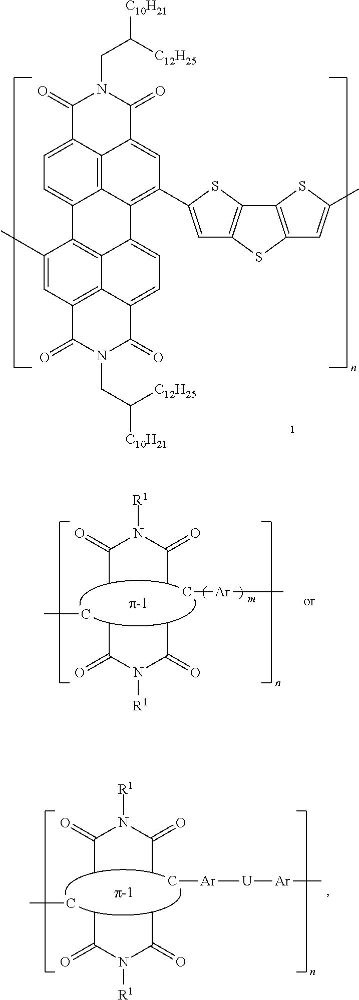

The n-type field effect transistors of the invention comprise a dopant layer which comprises at least one n-dopant material, and optionally at least one organic electron transport material. The n-dopant materials are used to “remotely” donate electron current carriers to the channel layers and spacer layers, and therefore preferably have an ionization energy, as measured by photoemission spectroscopy, of less than about 3.5 eV.

One well-known set of n-dopant materials are the alkali metals, lithium, sodium, potassium, or cesium. Such alkali metal n-dopants are known in the art to have some undesirable mobility within semiconductor materials, a property whose impact is lessened in the current inventions because of the presence of the spacer layer. Another known class of n-dopant materials which have less undesirable mobility are the metallocene dopants disclosed in US Patent Publication 2007/0295941, wherein a transition metal, lanthanide, or actinide metal atom is sandwiched between two aromatic or heteroaromatics rings. Preferred examples of such metallocene dopants include cobaltocene, Co(C₅Me₅)₂ (pentamethyl cobaltocene), or Fe(C₅Me₅)(C₆Me₆).

In many embodiments of the n-type field effect transistors, the dopant layer comprises a dispersion or mixture of the n-dopant material in an organic electron transport material. Preferably, the organic electron transport material has an electron affinity, as measured by inverse photoemission spectroscopy, that is equal to or smaller than the electron affinity of the organic semiconductor channel material, as measured by inverse photoemission spectroscopy, so that the electron donated by the n-dopant material and into the organic electron transport material then readily transfers to the “remote” channel layer, to increase its conductivity. Preferably, the organic electron transport material has an electron affinity, as measured by inverse photoemission spectroscopy, of less than about 3.0 eV.

Preferably, the organic electron transport material has an electron mobility that is smaller than the electron mobility of the organic semiconductor channel material by a factor of about 100 to about 100,000.

Examples of suitable organic electron transport material is copper or zinc phthalocyanine, or Alq₃, a substituted phenanthroline derivative, such as BCP, or an optionally substituted hexazatrinaphthalene (HATNA) based material, (whose structure is shown below and whose synthesis was reported by Skujins and Webb, Tetrahedron 1969, 25, 3935, and Barlow et al in Chem. Eur. J. 13, 3537 (2007).

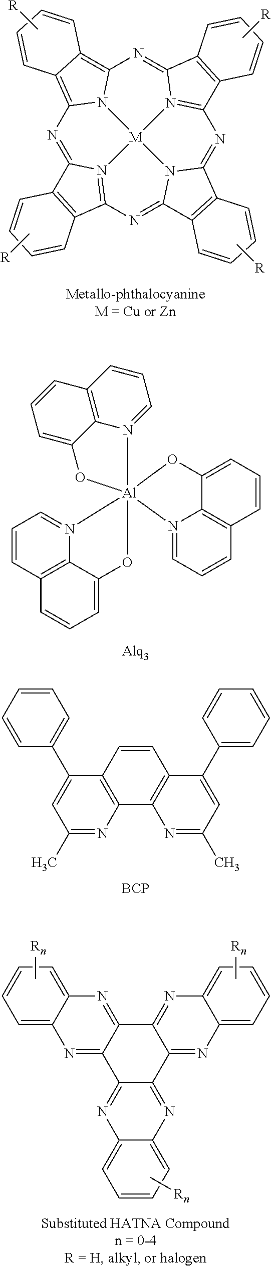

The inventions described herein also relate to various methods for making the structures and transistors disclosed above.

The n-type field effect transistors of the inventions also comprise a spacer layer disposed between and in electrical or physical contact with the channel layer and the dopant layer, comprising an organic semiconducting spacer material. The organic semiconducting spacer materials also typically have a relatively low lying LUMO, so as to be capable of readily accepting electrons from the dopant layer, and mediating their transfer to the remote channel layer. Typically, the organic semiconducting spacer material has an electron affinity, as measured by inverse photoemission spectroscopy, that is equal to or smaller than the electron affinity of the organic electron transport material, as measured by inverse photoemission spectroscopy. The organic semiconducting spacer materials typically have electron mobility that is smaller than the electron mobility of the organic semiconductor channel material by a factor of about 100 to about 100,000.

Examples of organic semiconducting spacer materials useful in the n-type field effect transistors include copper or zinc phthalocyanine, Alq₃, or substituted phenanthrolines such as BCP.

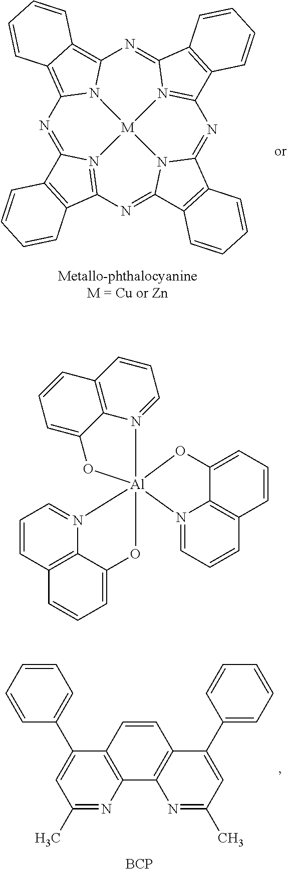

### Processes for Making the Devices

The various physical forms and devices and field effect transistors, including bottom gate, top contact, and bottom contact, top gate field effect transistors, can be made via the standard techniques for synthesizing organic electronic devices well known to those of ordinary skill in the art of organic electronics, as illustrated in part by the various pieces of prior art referenced herein and incorporated by reference herein. Examples of such techniques include direct vacuum deposition or co-deposition, or solution processes in which film forming materials such as polymers are dissolved in common organic solvents, then applied as solutions to solid substrates by “spinning,” as exemplified below, or liquid jet printing.

To specifically recite some non-limiting examples, in some embodiments, the inventions described and claimed herein relate to methods of making remotely p-doped bottom-gate, top contact field effect transistors comprising the steps of
a. obtaining a substrate and depositing thereon a conductive material to form the gate electrode;
b. forming or depositing over the gate electrode a gate insulating layer;
c. depositing over the gate insulating layer the least one organic semiconductor channel material to form the channel layer;
d. depositing or co-depositing over the channel layer at least one organic semiconducting spacer material, to form the spacer layer,
e. depositing over the spacer layer at least one p-dopant material and optionally at least one organic hole transport material, to form the dopant layer, and
f. depositing over the dopant layer source and drain electrodes.

In some embodiments, the inventions described and claimed herein relate to methods of making bottom-contact, top gate field effect transistor comprising the steps of
a. obtaining a substrate and depositing thereon source and drain electrodes
b. forming or depositing over the source and drain electrodes at least one organic semiconductor channel material, to form the channel layer;
c. depositing over the channel layer the least one organic semiconducting spacer material to form the spacer layer;
d. depositing or co-depositing over the spacer layer at least one p-dopant material and optionally at least one organic hole transport material, to form the dopant layer;
e. depositing on the dopant layer at least one gate insulating material, to form the gate insulating layer, and
f. depositing on the gate insulating layer a gate electrode.

In some embodiments, the inventions described and claimed herein relate to methods of making remotely n-doped bottom-gate, top contact field effect transistor of any one of claims 30-49 comprising the steps of
a. obtaining a substrate and depositing thereon a conductive material to form the gate electrode;
b. forming or depositing over the gate electrode a gate insulating layer;
c. depositing over the gate insulating layer the least one organic semiconductor channel material to form the channel layer;
d. depositing or co-depositing over the channel layer at least one organic semiconducting spacer material, to form the spacer layer,
e. depositing over the spacer layer at least one n-dopant material and optionally at least one organic electron transport material, to form the dopant layer, and
f. depositing over the dopant layer a conductive material, to form source and drain electrodes.

In some embodiments, the inventions described and claimed herein relate to methods of making remotely n-doped bottom-contact, top gate field effect transistor of any one of claims 30-49 comprising the steps of
a. obtaining a substrate and depositing thereon a conductive material to form source and drain electrodes
b. forming or depositing over the source and drain electrodes at least one organic semiconductor channel material, to form the channel layer;
c. depositing over the channel layer the least one organic semiconducting spacer material to form the spacer layer,
d. depositing or co-depositing over the spacer layer at least one n-dopant material and optionally at least one organic electron transport material, to form the dopant layer,
e. depositing on the dopant layer at least one gate insulating material, to form the gate insulating layer, and
f. depositing on the gate insulating layer a gate electrode.

It should be understood that the two embodiments of methods for making the remotely doped transistors above refer to various materials and/or layers of the transistors themselves, for which many sub-embodiments were described above with respect to the transistors. Any of such sub-embodiments of the transistors are also hereby also contemplated as sub-embodiments of the methods for making the remotely doped transistors described immediately above.

### EXAMPLES

The various inventions described above are further illustrated by the following specific examples, which are not intended to be construed in any way as imposing limitations upon the scope of the invention disclosures or claims attached herewith. On the contrary, it is to be clearly understood that resort may be had to various other embodiments, modifications, and equivalents thereof which, after reading the description herein, may suggest themselves to one of ordinary skill in the art without departing from the spirit of the present invention or the scope of the appended claims.

### Example 1

### UPS Spectroscopic Studies of P-Doped NPD Films in Contact with Pentacene

In order to experimentally study the energetics of interfaces between p-doped NPD and pentacene, and confirm that hole transfer occurs from the p-doped NPD to the pentacene, the following ultra-violet photoelectron spectroscopic studies were carried out.

In a first experiment, a 60 Å, α-NPD film doped with 1% Mo(tfd)₃ (see structures below) was prepared by ultra high vacuum co-evaporation of α-NPD (H. W. Sands, sublimed grade) with 1% Mo(tfd)₃ (synthesized and purified as described by Davidson and Holm, Inorganic Syntheses, Volume X, pg 8-23, McGraw-Hill Book Co. Inc, New York, 1967) at 1 Å/s onto a gold substrate.

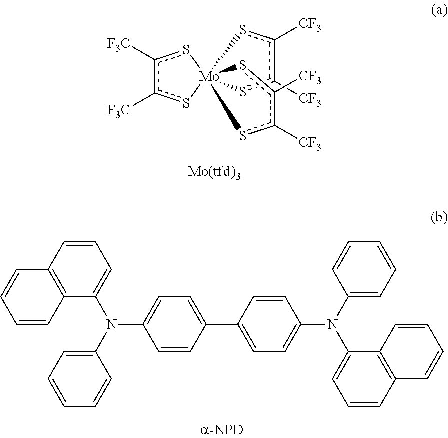

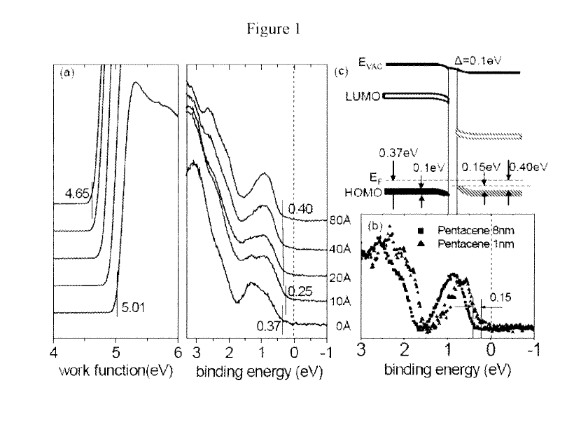

The UPS spectrum of the resulting p-doped NPD film (bottom curve of FIG. 1a) shows the edge of the highest occupied molecular orbital (HOMO) at 0.37 eV below the Fermi level, E_{F}, (E_{F} is measured independently on a clean surface of gold electrically connected to the sample). The HOMO position of the p-doped α-NPD film is ˜0.6 eV above its position with respect to E_{F} previously observed for intrinsic α-NPD deposited on gold, indicative of p-type doping and in excellent agreement with previous measurements on α-NPD:Mo(tfd)₃. (See Qi et al, J. Amer. Chem. Soc. 2009, 131, 12530-12531, and Wan et al, Organic Electronics 6 (2005) 47-54.)

The deposition of 10 Å of pentacene onto the p-doped α-NPD film shifts the onset of photoemission toward higher binding energy, suggesting a decrease in work function due to a positive charge transfer from α-NPD to pentacene. Without wishing to be bound by theory, the charge transfer may be due to the fact that the pentacene ionization energy (5.0 eV) is essentially equal to the work function of p-doped α-NPD. The system can reach thermodynamic equilibrium by transferring some charges to shift the pentacene HOMO below E_{F}.

The energetic positions of the α-NPD and pentacene HOMO at the interface can be obtained by decomposing the respective contributions to the α-NPD+10 Å pentacene spectrum (FIG. 1a). The result (FIG. 1b) shows a 0.15 eV molecular level displacement to higher binding energy from that of pentacene at the interface to that in a 80 Å pentacene overlayer. The ionization energy of the latter matches very well with previous reports. There is a corresponding 0.1 eV displacement of the α-NPD HOMO position as well (spectrum not shown), which is consistent with the transfer of a positive charge from p-doped α-NPD to the interface pentacene molecules.

### Example 2

### Electrical Characteristics of Devices Comprising Pentacene Layers, p-Doped Layers of α-NPD, and/or Optional Spacer Layers

The charge transfer and electrical conductivity characteristics of non-gated devices comprising pentacene layers, optional spacer layers, and dopant layers comprising α-NPD as an organic hole transport material and Mo(tfd)₃ as a p-dopant material, were investigated as follows:

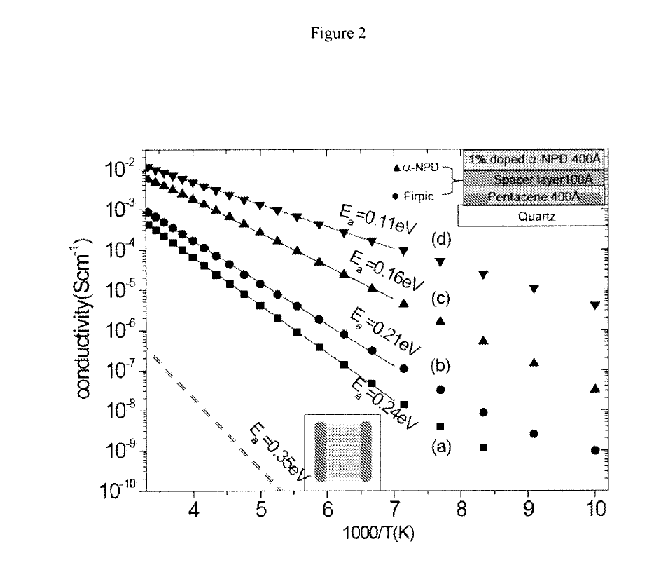

In a set of experiments, non-gated devices comprising layers of pentacene (always on the bottom) and additional semiconductor overlayer films of α-NPD (doped or undoped) or FIrpic (undoped) were grown sequentially on a quartz substrate previously pre-patterned with interdigitated Ti 20 Å/Au 300 Å electrodes (electrode width: 5 mm; inter-electrode gap: 150 μm, see diagram in Inset of FIG. 2).

The layers of the devices were deposited and electrical measurements performed in a dual-chamber (base pressure 5×10⁻¹⁰ Torr) without ambient exposure.

Four devices were produced and investigated: (a) pentacene (400 Å); and three additional devices having the layer structure: pentacene (400 Å)/[spacer layer]/p-doped (1%) α-NPD (400 Å), wherein the spacer layer was either (b) FIrpic (100 Å); (c) undoped α-NPD (100 Å); and (d) no spacer layer. “FIrpic” is bis(2-(4,6-difluorophenyl)pyridyl-N,C2′)iridium(III) picolinate, a semiconductor obtained from Universal Display Corp. Deposition rates for pentacene and p-doped α-NPD were controlled for all devices at 0.2 Å/s and 1.0 Å/s, respectively, to minimize variations between devices.

Conductivity measurements on the devices were performed in the dark, with the device placed on a temperature-controlled stage, and measurements performed at 10 K intervals between 300 K and 100K. The current-voltage (I-V) characteristics were recorded with a Keithley source meter 2400.

Conductivity (σ) vs. T plots for the devices are shown in FIG. 2. σ decreases with temperature following a simple Arrhenius law σ˜exp└−Eₐ/(k_{B}T)┘, where Eₐ is the activation energy, in accord with a trap and release process, as expected for thermally assisted hopping transport. See Vissenberg et al, Phys. Rev. B, Vol 57(20), 12964-12967, 1998. At temperatures below 150 K, Eₐ becomes slightly temperature dependent and decreases slowly.

While not wishing to be bound by theory, it is believed that the activation energy is likely determined predominantly by the energy distribution of the trap states and occupation of these states in the pentacene layer. Adding the p-doped α-NPD layer directly on top of pentacene (device (d)) increases the room temperature conductivity from 4.2×10⁻⁴ S/cm to 1.1×10⁻² S/cm, probably as a result of the charge transfer of holes to the pentacene discussed earlier. Eₐ decreases from 0.24 eV to 0.11 eV, suggesting that the hole from the dopant layer fill the deeper traps in the pentacene layer and lower the average energy required for holes hopping between localized states. It is important to clarify that conduction in the p-doped α-NPD overlayer of the devices likely does not contribute in any way to the increased conductivity, since an α-NPD layer, even highly p-doped, has a conductivity that is several orders of magnitude lower than undoped pentacene, due to its substantially lower hole mobility. See Matsushima et al, Thin Solid Films, 517 (2008) 74-877. The dashed curve in FIG. 2 represents the conductivity vs. T separately measured for a 5000 Å thick α-NPD: 1.7% Mo(tfd)₃ film.

For devices (b) and (c), a 100 Å spacer layer composed of either FIrpic or undoped α-NPD, respectively, is placed between pentacene and p-doped α-NPD. In device (c), with the α-NPD spacer layer, the room temperature conductivity of the device drops by 50% with respect to device (d), which has no spacer layer.

The conductivity drops even more significantly more with a FIrpic interlayer, device (b). FIrpic (obtained from Universal Display Corp.) has an ionization energy of 6 eV (vs. 5.4 for α-NPD) and has been used in OLEDs as a hole blocking material. See V. I. Adamovich et al., Org. Electron. 4, (2003) 77. The 0.6 eV higher energy barrier for holes that the FIrpic spacer layer creates between p-doped α-NPD and pentacene layers blocks the charge transfer more efficiently than the α-NPD spacer layer, leading to a significantly lower room-temperature conductivity and higher activation energy in the device. AFM measurements on devices (b) and (c) devices (not shown here) showed that α-NPD and FIrpic do not crystallize significantly on pentacene, which is important when comparing the two device behaviors. Yet, the spacer layer is only 100 Å thick and some leakage due to the roughness of the organic film is to be expected, consistent with the incomplete blocking of the charge transfer in device (b).

### Example 3

### Comparison of Undoped and Remotely Doped Pentacene Field Effect Transistors

The use of remote doping to improve the performance of field effect transistors was demonstrated as follows:

Four top contact, bottom gate transistors were fabricated on a heavily doped p. Si wafer, approximately 100 microns, with a 3000 Å oxide layer provided by Silicon Quest International. A gate electrode was made by depositing aluminum (5000 Å) on the back of the silicon wafer and annealing in forming gas (a mixture of hydrogen and nitrogen) at 450-C to form an Ohmic contact. A pentacene channel layer (60 Å) was grown on the SiO₂ gate dielectric surface in ultra high vacuum. Optional spacer and dopant layers (described below) were also grown in ultra high vacuum, then the devices were briefly exposed to air (<2 minutes) while being transferred to a vacuum chamber for deposition of gold source and drain electrodes (800 Å thick) through a stencil mask, to produce an OFET channel 100 μm long and 2 mm wide.

Transistor (a) (see FIG. 2) comprised only a 300 Å pentacene layer.

Transistor (b) also comprised a 300 Å undoped α-NPD “spacer” layer over a 60 Å pentacene layer.

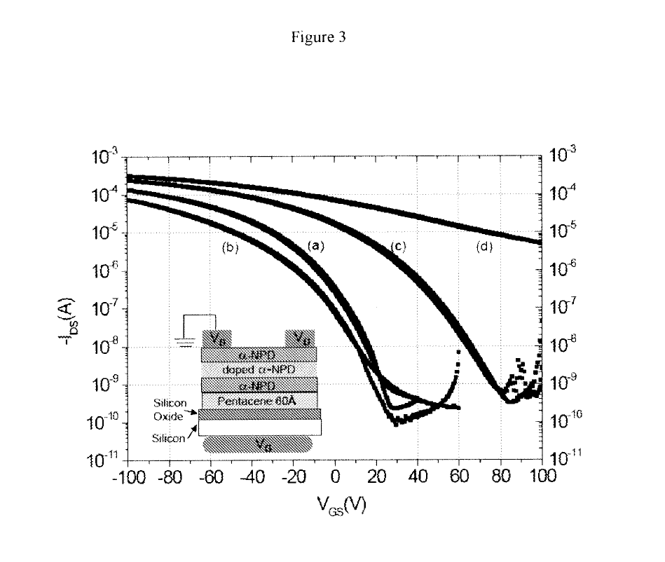

Remotely doped transistor (c) further comprised a 100 Å undoped α-NPD “spacer” layer over the pentacene layer, and also a 40 Å layer of α-NPD co-deposited with 5% Mo(tfd)₃ under vacuum, as a “dopant” layer over the α-NPD spacer layer, followed by an additional protective overlayer of 100 Å undoped α-NPD, which was followed by deposition of the gold source and drain electrodes. See FIG. 3.

Remotely doped transistor (d) did not comprise an undoped “spacer” layer over the pentacene layer, but did comprise a vacuum deposited 40 Å “dopant” layer of α-NPD that was co-deposited under vacuum with 5% Mo(tfd)₃ under vacuum over the pentacene layer, followed by an additional protective overlayer of 200 Å undoped α-NPD (which also keeps the thicknesses of the transistors roughly constant), then was completed by deposition of the gold source and drain electrodes on the α-NPD overlayer.

The electrical characteristics of transistors (a)-(d) were measured under a nitrogen atmosphere using an HP semiconductor analyzer 4155B.

As can be seen in FIG. 3, the source-drain current IDS at VDS=−40 V of transistor (b), having a 60 Å pentacene channel layer and a 300 Å undoped α-NPD overlayer was only slightly smaller than that for 300 Å pentacene transistor (a), and both transistors (a) and (b) exhibited an “on/off” response to applied gate voltage typical of pentacene transistors. This result is explainable, because first, the current in organic field effect transistors is believed to flow primarily in the first few layers close to the dielectric interface, see Dinelli et al, Physical Review Letters, Vol 92 (11), 116802-1-116802-4. Secondly, Au likely diffuses sufficiently deeply during deposition to penetrate the 300 Å α-NPD layer and into the pentacene layer to make direct contact with the conducting channel. Thirdly, α-NPD has much poorer hole mobility than pentacene; therefore, it is reasonable to assume that the current carrying holes are largely confined in the thin pentacene layer adjacent to the gate dielectric, so that pentacene thickness is unimportant.

In transistor (d), a 40 Å 5% Mo(tfd)₃ doped α-NPD dopant layer was deposited directly on the pentacene channel layer, without a spacer layer, followed by a 200 Å undoped α-NPD overlayer for maintaining an approximately constant total thickness of the transistor. The source-drain current at zero gate voltage (VGS=0 V) in doped transistor (d) was almost three orders of magnitude higher than in the undoped pentacene transistors ((a) and (b)), demonstrating the large potential benefits of remote doping techniques. However, the source-drain current was barely modulated by gate bias, in accord with other reports on directly doped-channel OFETs previously discussed above, and the pentacene OFET doped with a full external layer of F₄-TCNQ reported by Abe et al, Appl. Phys. Lett. 87, 153506 (2005).

However, when a 100 Å undoped α-NPD spacer layer was placed between the pentacene channel layer and the Mo(tfd)₃ doped α-NPD dopant layer in transistor (c), current modulation by the gate electrode was possible, and the threshold voltage dramatically decreased, and the transistor could be switched off. Moreover, the drain-source current in the presence of the spacer layer of transistor (c) was not significantly reduced due to the small charge transfer barrier created by the α-NPD spacer layer, as was also seen in the conductivity measurements presented above.

Without wishing to be bound by theory, it is believed that the gate field controls both charge injection from the electrode and hole transfer to the channel layer from dopant layer. However, it is reasonable to assume that the latter is more weakly affected by the gate field because the threshold voltage in remotely doped transistors (c) and (d) was increased. Because of that, the field-dependent motilities, to a first approximation, can be obtained by usual differentiation of the transfer curves in the linear region (VDS=−1V). The saturated hole mobility at high operating gate voltage for the remotely doped devices (d) and (c) is 0.29 cm²/(Vs) and 0.25 cm²/(Vs), respectively, substantially increased from 0.095 cm²/(Vs) measured for the undoped transistor (b). This is consistent with a dopant induced decrease in activation energy for hole transport, attributable to the filling of deep traps in the pentacene layer by remote doping of holes into the pentacene.

### Example 4

### A Remotely n-Doped Field Effect Transistors Formation of a Remotely n-Doped OFET

A remotely n-doped bottom gate organic field effect transistor (OFET) is built on a p⁺⁺-Si wafer (250 micron thick) with a 1500 Å oxide layer from Silicon Quest International (Santa Clara, Calif., USA). The bottom gate electrode is made by depositing aluminum (5000 Å) on the back of the Si wafer and annealing in forming gas (H₂/N₂) at 450° C. to form an Ohmic contact. The silicon oxide on the other side of the wafer is spin-coated with a 1000 Å layer of hydroxyl-free gate dielectric (divinyltetramethylsiloxane-bis(benzocyclobutene, “BCB”, see L. L. Chua, P. K. H. Ho, H. Sirringhaus, and R. H. Friend, Appl. Phys. Lett. 84, 3400-3402 (2004)). A C₆₀ fullerene film (60 Å) is deposited next in vacuum (pressure <10⁻⁸ Torr) to form an electron-conducting channel layer of the transistor. This is followed by the vacuum deposition (pressure <10⁻⁸ Torr) of an undoped spacer layer (100 Å) of 5,6,11,12,17,18-hexaazatrinaphthylene (HATNA) or bis(2-(4,6-difluorophenyl)pyridyl-N,C2′)iridium(III) picolinate (FIrpic) on the channel layer. An n-doped layer (100 Å) is then formed on the spacer layer by depositing HATNA doped with 1 wt % decamethylcobaltocene (Co(C₅Me₅)₂, Sigma-Aldrich). Doping is achieved by depositing HATNA in a pre-determined background pressure of decamethylcobaltocene, See Calvin K. Chan, Wei Zhao, Stephen Barlow, Seth R. Marder, and Antoine Kahn, Org. Elect. 9, 575 (2008). The decamethylcobaltocene pressure is controlled by leaking the molecules through a leak-valve into the growth chamber from an ampoule heated at 100° C. Finally, gold source and drain contacts (800 Å thick) are vacuum deposited on the n-doped layer (pressure <10⁻⁸ Torr) through a stencil mask. The OFET channel is 100 μm long and 2 mm wide.

### Example 5

### A Remotely n-Doped Field Effect Transistor with a Solution Processed Polymer as Channel Layer

P(NDI₂OD-T₂) (see Yahn et al, Nature 457, 679-686, 5 Feb. 2009, and available commercially from Polyera of Skokie Ill. as N2200), is one of the best known and most efficient polymeric n-type organic semiconductors known, and has the structure shown below, is solution processable, and has been reported to have electron mobilities between about 0.1-0.8 cm²/vs. The electron affinity of NDI was measured by inverse photoemission spectroscopy (IPES) and found to be 3.92 eV.

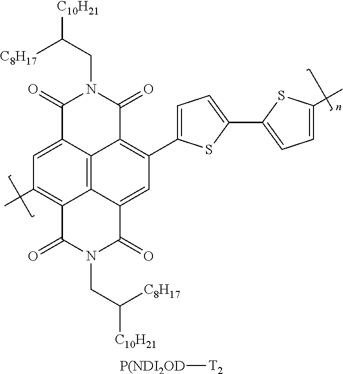

A remotely n-doped bottom gate organic field effect transistor (OFET) is built on a p⁺⁺-Si wafer (250 micron thick) with a 1500 Å oxide layer from Silicon Quest International (Santa Clara, Calif., USA). The bottom gate electrode is made by depositing aluminum (5000 Å) on the back of the Si wafer and annealing in forming gas (H₂/N₂) at 450° C. to form an Ohmic contact. The silicon oxide on the other side of the wafer is spin-coated with a 1000 Å layer of hydroxyl-free gate dielectric (divinyltetramethylsiloxane-bis(benzocyclobutene, “BCB”, see L. L. Chua, P. K. H. Ho, H. Sirringhaus, and R. H. Friend, Appl. Phys. Lett. 84, 3400-3402 (2004)).

P(NDI2OD-T2) solutions are prepared by dissolving 15.8 mg P(NDI2OD-T2) in 1 ml of chlorobenzene in an N₂ glovebox, then the solution is spin-coated onto the silicon/silicon oxide substrates at a spin speed of 2000 RPM for 40 seconds, to form a film on the substrate (˜50 nm thick).

This is followed by the vacuum deposition (pressure <10⁻⁸ Torr) of an undoped spacer layer (100 Å) of copper phthalocyanine (CuPc) (EA=3.3 eV) on the channel layer.

An n-doped layer (100 Å) is then deposited on the spacer layer by vacuum depositing PTCBi (structure shown below having an electron affinity of ˜4.0 eV) that is directly n-doped with 1 wt % decamethylcobaltocene (Co(C₅Me₅)₂, Sigma-Aldrich). Doping is achieved by depositing PTCBi in a pre-determined background pressure of decamethylcobaltocene, via a procedure similar to that described by Calvin K. Chan, Wei Zhao, Stephen Barlow, Seth R. Marder, and Antoine Kahn, Org. Elect. 9, 575 (2008). The decamethylcobaltocene pressure is controlled by leaking the molecules through a leak-valve into the growth chamber from an ampoule heated at 100° C.

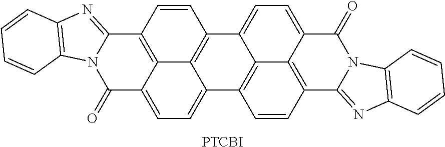

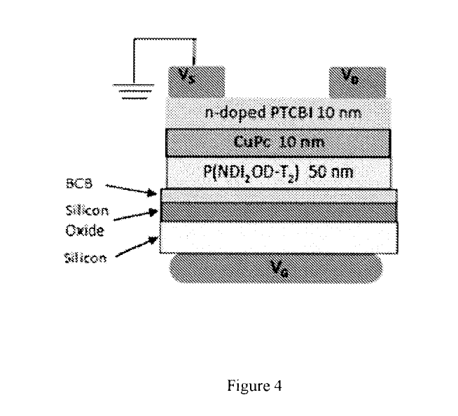

Finally, gold source and drain contacts (800 Å thick) are vacuum deposited on the n-doped layer (pressure <10⁻⁸ Torr) through a stencil mask. The OFET channel is 100 μm long and 2 μm wide. A schematic diagram of the device is shown in FIG. 4.

### CONCLUSIONS

The above specification, examples and data provide exemplary description of the manufacture and use of the various compositions and devices of the inventions, and methods for their manufacture and use. In view of those disclosures, one of ordinary skill in the art will be able to envision many additional embodiments of the inventions disclosed and claimed herein to be obvious, and that they can be made without departing from the spirit and scope of the invention. The claims hereinafter appended define some of those embodiments.

1. A p-doped field effect transistor comprising
a) a channel layer comprising at least one organic semiconductor channel material;
b) a dopant layer, which comprises at least one p-dopant material and optionally at lease one organic hole transport material;
c) a spacer layer disposed between and in electrical contact with both the channel layer and the dopant layer, comprising at least one organic semiconductor spacer material;
d) source and drain electrodes in electrical contact with the channel layer, and
e) a gate electrode in contact with a gate insulating layer.

2. The field-effect transistor of claim 1, wherein the organic semiconductor channel is an organic hole-transport material.

3. The field effect transistor of claim 1 wherein the organic semiconductor channel material has an intrinsic hole mobility larger than 1×10⁻³ cm²/(Vs).

4. The field effect transistor of claim 2 wherein the organic hole transport material is an organic compound comprising two or more conjugated aryl or heteroaryl rings and having an ionization energy, as measured by photoemission spectroscopy, of less than about 6.0 eV.

5. (canceled)

6. (canceled)

7. The field effect transistor of claim 1 wherein the organic semiconductor channel material comprises pentacene or a substituted pentacene derivative, rubrene or a reubrene derivative, a metal phthalocyanine, or a regioregular alkyl polythiophene.

8. (canceled)

9. (canceled)

10. (canceled)

11. (canceled)

12. The field effect transistor of claim 1 wherein the p-dopant material is a transition metal complex having the formula 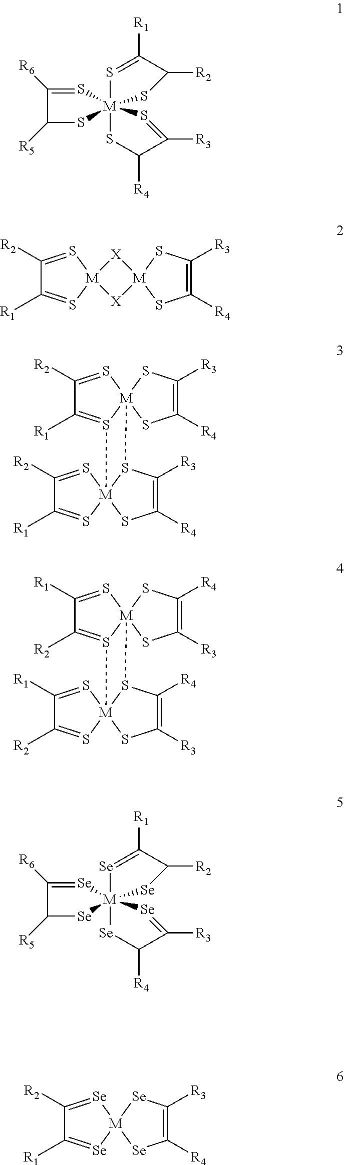
wherein M is a transition metal, preferably Cr, Mo, or W, and R₁-R₆ are independently selected from H, substituted or unsubstituted C₁-C₁₀ alkyl, C₁-C₁₀-Thienyl, prefluorinated alkyl, Phenyl, Tolyl, N,N-Dimethylaminophenyl, Anisyl, Benzoyl, CN, or COOR₇ where R₇ is C₁-C₅ alkyl; X is S, Se, NR₁₀, wherein R₁₀ is alkyl, prefluoroalkyl, cycloalkyl, aryl, hetero aryl, acetyl, or CN.

13. The field effect transistor of claim 1 wherein the p-dopant material is a transition metal complex having the formula 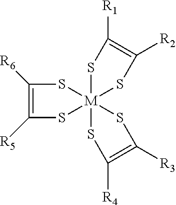
wherein M is Cr, Mo, or W, and R₁-R₆ are independently selected from a C₁-C₃₀ perfluoroalkyl cyano, or optionally substituted aryl or heteroaryl.

14. The field effect transistor of claim 1 wherein the p-dopant material is tetrafluoro-TCNQ.

15. The field effect transistor of claim 1 wherein the dopant layer comprises at least one semiconducting hole transport material.

16. The field effect transistor of claim 1 wherein the organic hole transport material has an ionization energy of greater than about 5.4 eV, as measure by photoemission spectroscopy, and a hole mobility that is smaller than the intrinsic hole mobility of the organic semiconductor channel material by a factor of about 100 to about 100,000.

17. The field effect transistor of claim 1 wherein the organic hole transport material is a compound comprising two to 10 conjugated triaryl amine subunits having the structure 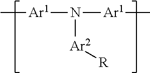
wherein Ar¹ and Ar² can be the same or different and comprise at least one phenyl or naphthyl ring, and R is a normal or branched C₁-C₁₈ alkyl group.

18. The field effect transistor of claim 1 wherein the organic hole transport material has one of the structures

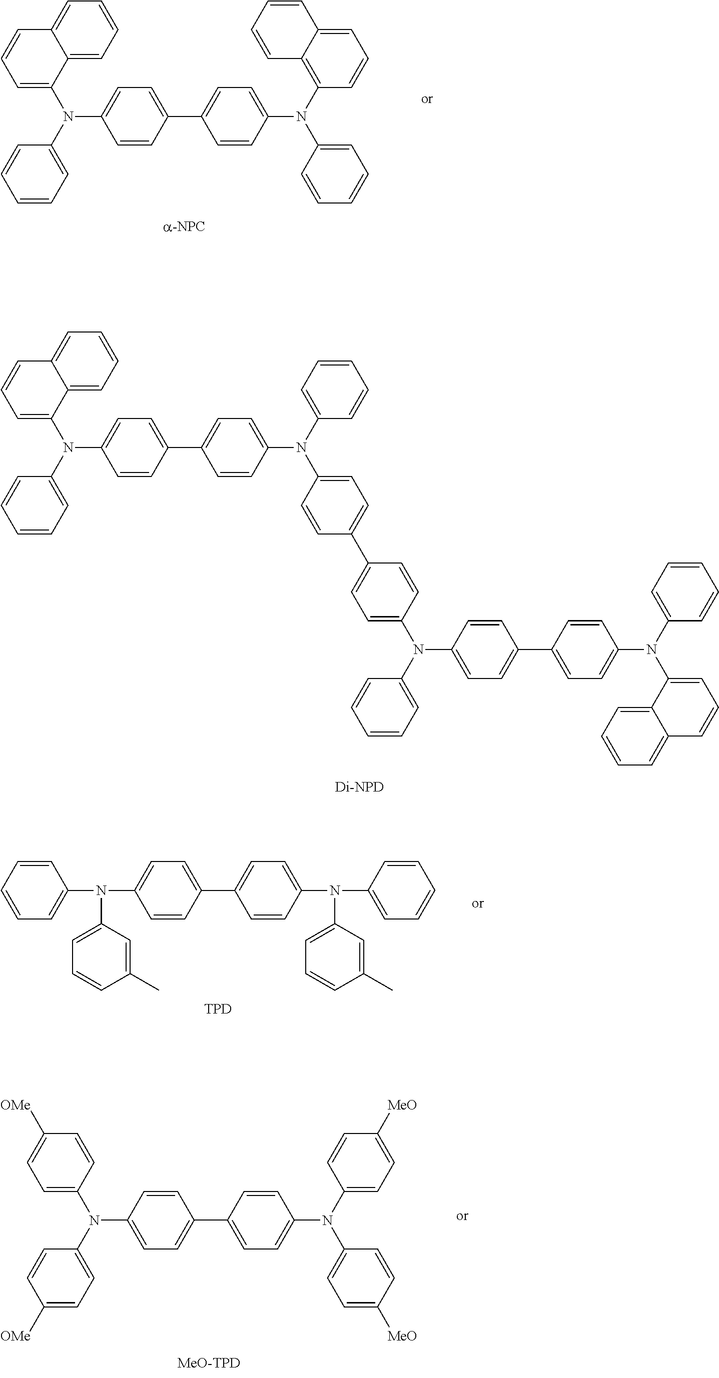

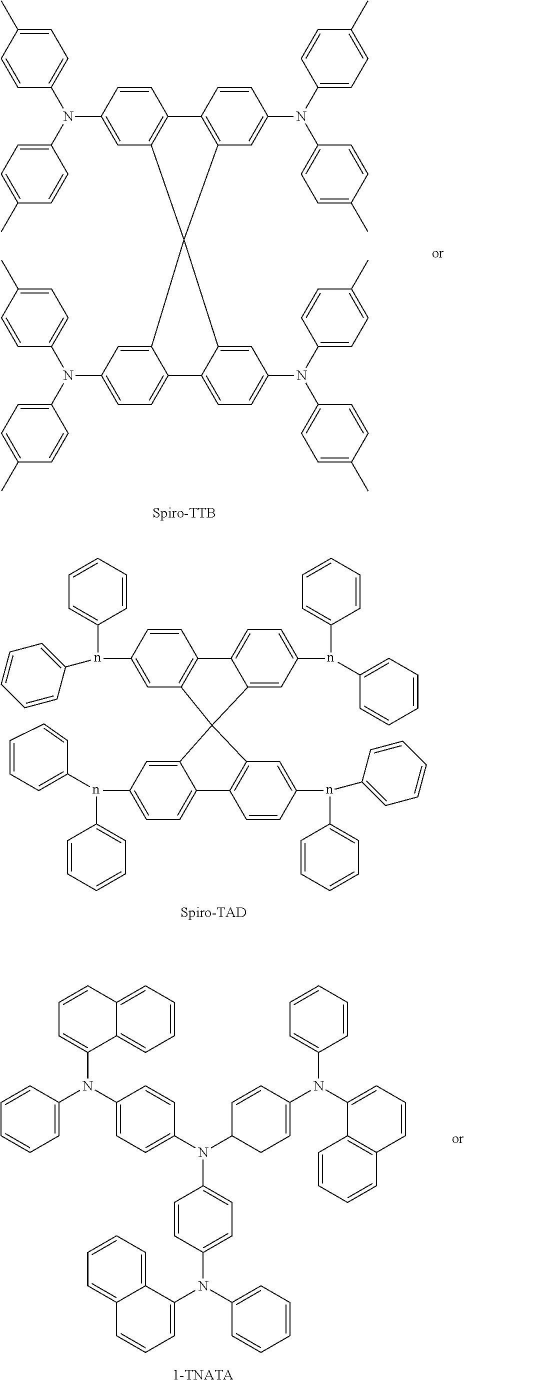

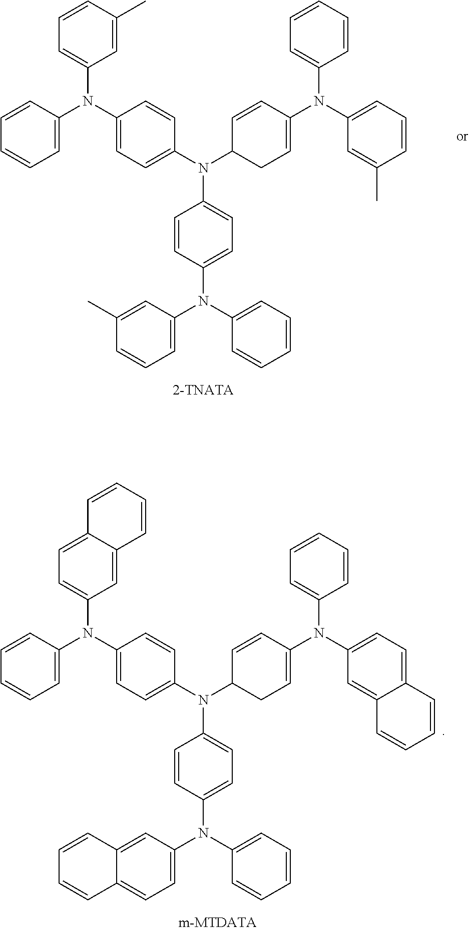 [SMILES: Cc1cccc(N(C2=CCC(N(c3ccc(N(c4ccccc4)c4cccc(C)c4)cc3)c3ccc(N(c4ccccc4)c4cccc(C)c4)cc3)C=C2)c2ccccc2)c1 ; C1=CC(N(c2ccc(N(c3ccccc3)c3ccc4ccccc4c3)cc2)c2ccc(N(c3ccccc3)c3ccc4ccccc4c3)cc2)CC=C1N(c1ccccc1)c1ccc2ccccc2c1]

19. (canceled)

20. The field effect transistor claim 1 wherein the organic semiconducting spacer material is an organic compound comprising two or more conjugated aryl or heteroaryl rings and having an ionization energy, as measured by photoemission spectroscopy, of greater than about 5.4 eV.

21. The field effect transistor of claim 1 wherein the organic semiconducting spacer material has a hole mobility that is smaller than the intrinsic hole mobility of the organic semiconductor channel material by a factor of about 100 to about 100,000.

22. (canceled)

23. The field effect transistor of claim 1 wherein the organic semiconducting spacer material is a polymeric or copolymeric hole carrier material.

24. The field effect transistor of claim 1 wherein the organic semiconducting spacer material is
i) α-NPD,
ii) FIrPic
iii) Alq₃.

25. The field effect transistor of claim 1 wherein the organic semiconducting spacer material is an organic compound comprising two or more conjugated aryl or heteroaryl rings and having an ionization energy, as measure by photoemission spectroscopy, of between about 6.0 and about 7.0 eV.

26. The field effect transistor of claim 1 wherein the organic semiconducting spacer material is an organic compound comprising an N-substituted carbazole.

27. (canceled)

28. A method of making a bottom-gate, top contact field effect transistor of any one of claims 1-27 comprising the steps of
a) obtaining a substrate and depositing thereon a conductive material to form the gate electrode;
b) forming or depositing over the gate electrode a gate insulating layer,
c) depositing over the gate insulating layer the lease one organic semiconductor channel material to form the channel layer;
d) depositing or co-depositing over the channel later at least one organic semiconducting spacer material, to form the spacer layer,
e) depositing over the spacer layer at least one p-dopant material and optionally at lease one organic hole transport material, to form the dopant layer, and
f) depositing over the dopant layer source and drain electrodes.

29. A method of making a bottom-contact, top gate field effect transistor of any one of claims 1-27 comprising the steps of
a) obtaining a substrate and depositing thereon source and drain electrodes
b) forming or depositing over the source and drain electrodes at least one organic semiconductor channel material, to form the channel layer,
c) depositing over the channel layer the least one organic semiconducting spacer material to form the spacer layer,
d) depositing or co-depositing over the spacey layer at least one p-dopant material and optionally at least one organic hole transport material, to form the dopant layer,
e) depositing on the dopant layer at least one gate insulating material, to form the gate insulating layer, and
f) depositing on the gate insulating layer a gate electrode.

30-52. (canceled)
